(19) United States
(12) Patent Application Publication
(10) Pub. No.: US 2026/0301659 A1
(43) Pub. Date: Oct. 1, 2026

(54) Optoelectronic Devices Including Selectable Anode and Cathode Regions Able to Drive Coupled PMOS or NMOS Transistors in a Complementary Push-Pull Configuration

(71) Applicant: Innovation Semiconductor Inc., Rochester, NY (US)

(72) Inventor: Matthew T. Hartensveld, Geneva, NY (US)

(21) Appl. No.: 19/656,900

(22) Filed: Apr. 23, 2026

Related U.S. Application Data
(63) Continuation-in-part of application No. 19/078,840, filed on Mar. 13, 2025.
(60) Provisional application No. 63/565,158, filed on Mar. 14, 2024.

(51) Int. Cl. G09G 3/32; H10H 29/30

(52) U.S. Cl. CPC G09G 3/32; H10H 29/30; G09G 2320/0626; G09G 2330/021

(57) ABSTRACT

Optoelectronic devices having simultaneously and independently addressable anode and cathode regions. They support a push-pull complementary transistor driving configuration that employs at least one PMOS transistor coupled to the p-type anode region and at least one NMOS transistor coupled to the n-type cathode region to drive each optoelectronic element in a complementary push-pull mode. Independent addressability of the cathode and anode is enabled by an electrically inactive p-type isolation region, which forms a depletion region with the n-type cathode to electrically isolate individual elements. The push-pull configuration provides enhanced switching speed, reduced static power dissipation, wider dynamic range, improved noise rejection, and greater design flexibility. The PMOS and NMOS transistors may be fabricated on a standard CMOS backplane wafer bonded to the optoelectronic element array, fully leveraging standard CMOS foundry capabilities for high-resolution micro-LED displays, detector arrays, data center optical interconnects, co-packaged optics, and optical transceiver arrays.

### CROSS-REFERENCE TO RELATED APPLICATIONS

This application is a continuation-in-part of U.S. patent application Ser. No. 19/078,840, filed Mar. 13, 2025, which claims benefit of U.S. Provisional Patent Application No. 63/565,158, filed Mar. 14, 2024, the entirety of both applications are herein incorporated by reference.

### BACKGROUND OF THE INVENTION

### 1. Field of the Invention

This invention relates generally to optoelectronic devices usable in optoelectronic connectors and transceivers that are interposed between semiconductor devices that originate, transmit, carry, or receive data flows, including chip-to-chip, chip-to-fiber, fiber-to-chip, and like connections. More particularly, this technology relates to optoelectronic devices that can support simultaneous and/or independent complementary transistor driving configurations employing both NMOS and PMOS transistors, including in a push-pull circuit topology to independently and simultaneously drive current through the cathode and anode, respectively, of each optoelectronic element within optoelectronic devices having electrically isolated anode and cathode regions.

### 2. Prior Art Description

Elements in optoelectronic devices, such as conventional light-emitting diodes (LEDs) or photodetectors, and the devices based on arrays of such elements, are composed of various active layers configured during semiconductor growth and processing. These active layers conventionally include an electron rich n-type region, a hole rich p-type region, and a multiple quantum well (MQW) region between the n-type and p-type regions. The MQW region is composed of multiple individual quantum wells which possess a smaller energy bandgap due to alloying, which are positioned between higher energy bandgap materials. The smaller energy bandgap quantum wells confine electrons and holes to facilitate recombination for light emission in the case of an LED, or light absorption by a detector. By way of example, for LEDs or photodiodes based on the III-N material system, Indium is typically alloyed with gallium nitride (GaN) in different amounts to shrink the bandgap of the quantum wells.

Optoelectronic devices, such as micro-LEDs and photodetectors, are increasingly used in high-resolution displays, sensor arrays, and data communication systems. Conventional optoelectronic device architectures employ a common cathode configuration where a shared n-type region serves as the cathode for all elements in an array. This common cathode architecture limits the driving circuitry to PMOS transistor configurations integrated through the p-type anode of each element.

### BRIEF DESCRIPTION OF THE INVENTION

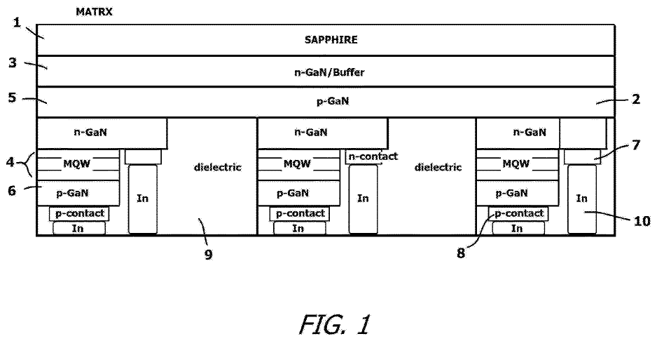

FIG. 1 is an exemplary cross-sectional view of an optoelectronic system incorporating a push-pull complementary driving configuration;

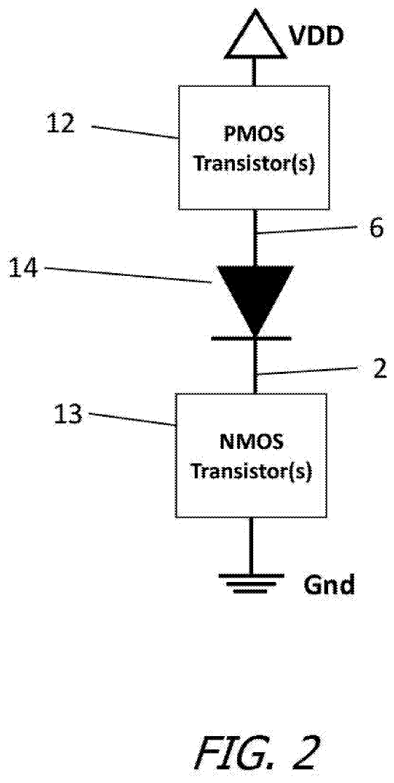

FIG. 2 shows a push-pull complementary transistor driving circuit for a single optoelectronic element;

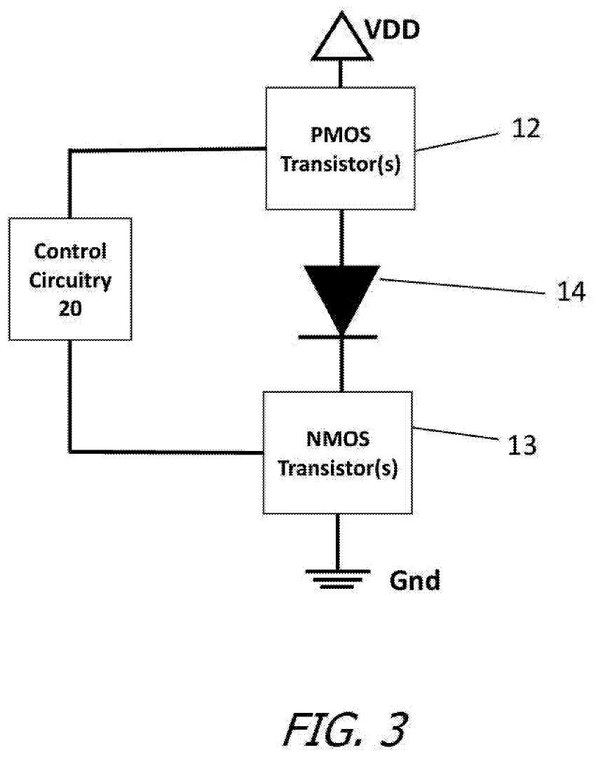

FIG. 3 shows a push-pull complementary transistor driving circuit with control circuitry;

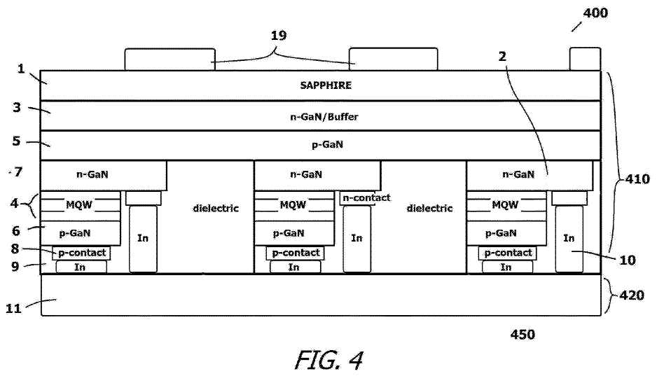

FIG. 4 is a second cross-sectional view of an optoelectronic system incorporating the push-pull complementary driving configuration;

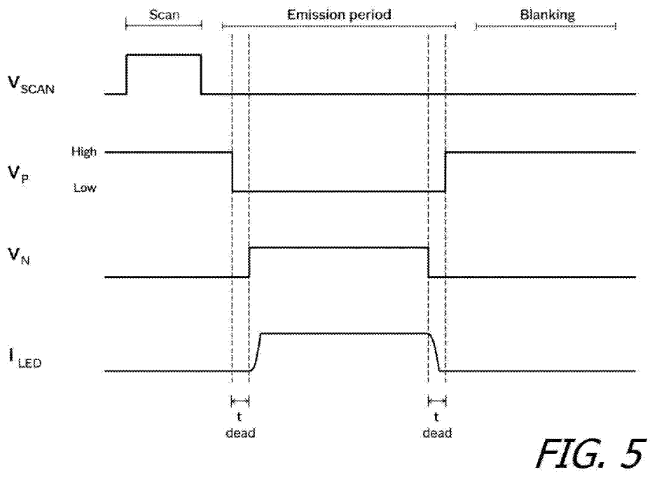

FIG. 5 is a timing diagram illustrating exemplary complementary control signals applied to PMOS transistor(s) and NMOS transistor(s) during operation of a push-pull driving configuration; and

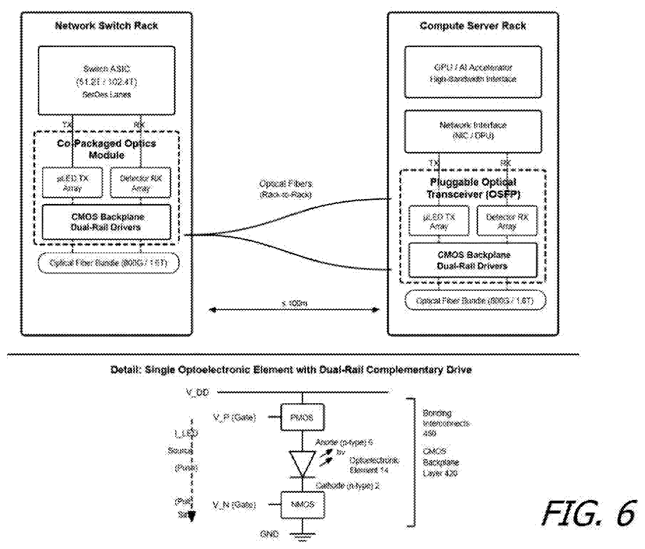

FIG. 6 shows a data center optical interconnect system with two exemplary deployment configurations of a push-pull complementary driving configuration.

### SUMMARY OF THE INVENTION

The limitation of a common cathode can be addressed by introducing an electrically inactive p-type isolation region that enables unique, independently addressable cathode and anode regions for each optoelectronic element. Such an architecture enables the use of NMOS transistors coupled to the cathode, or alternatively PMOS transistors coupled to the anode, providing significant flexibility in the design of backplane control circuitry. However, the specific circuit topology for simultaneously leveraging both transistor types to drive a single optoelectronic element in a complementary push-pull configuration has not been fully described. A push-pull configuration, in which one transistor sources current while the complementary transistor sinks (removes) current through the same element, can provide substantial performance advantages beyond those achievable by either transistor type alone.

Conventional active-matrix backplane circuits for micro-LED displays typically employ a single transistor type per pixel, either PMOS or NMOS, to control current flow through the optoelectronic element. Single-transistor-type circuits are limited in their ability to achieve rail-to-rail output voltage swing, symmetric driving capability, and optimal power efficiency simultaneously. Furthermore, single-transistor-type drivers can suffer from increased static power dissipation, limited dynamic range, and reduced switching speed at the extremes of their operating range. Additionally, as micro-LED displays push toward higher resolutions exceeding thousands of pixels per inch and higher refresh rates to meet the demands of augmented reality (AR) and virtual reality (VR) applications, the performance demands on the backplane driving circuitry become increasingly stringent. Single-transistor-type driving circuits face challenges in meeting these demands without significant trade-offs in power consumption, pixel area, or driving precision.

In a related aspect, the scope and scale of computing and networking operations have become increasingly complex, with data volumes growing and performance requirements becoming more demanding. This trend is expected to accelerate as AI use expands and the construction of large AI data centers strains available power sources. Management of significant data streams is expected to outgrow traditional, fully electronic systems, with attention increasingly focused on hybrid data systems in which optical elements or circuits augment or replace electronic elements due to higher potential data transmission rates and lower power requirements. Data center optical interconnects, including chip-to-chip transceivers, rack-to-rack optical links, and co-packaged optics on switch ASICs, face the same switching speed, power efficiency, and dynamic range demands as display applications. Current single-transistor-type drivers are insufficient for next-generation 800G and 1.6T optical links, where modulation bandwidth and energy per bit are critical constraints.

Accordingly, there is a need for optoelectronic element architectures, and those of devices based on such elements, to support driving configuration that simultaneously leverage the characteristics of both NMOS and PMOS transistors in a manner that increases data rate capabilities and decreases power required per bit of transmitted data. This is particularly true for applications spanning high-resolution displays, optical communications, and data center interconnects, each facing growing demands to manage data streams at higher speeds and with greater power efficiency. Examples of this technology relate to optoelectronic elements and devices incorporating a push-pull complementary transistor driving configuration that employs both an NMOS transistor and a PMOS transistor to independently and optionally simultaneously control current flow through each optoelectronic element. This configuration is enabled by the availability of simultaneously and independently addressable cathode and anode regions provided by means of an electrically inactive p-type isolation region that both physically and electrically separates each element in the device.

In examples of this technology, a PMOS transistor is coupled to the p-type anode region of an optoelectronic element and an NMOS transistor is coupled to the n-type cathode region of the same element. The PMOS transistor is configured to source current into the element through the anode, while the NMOS transistor is configured to sink current from the element through the cathode. Together, these transistors form a push-pull driver stage that provides complementary and independent control of the current flowing through the optoelectronic element.

In accordance with further examples, the push-pull configuration provides a number of advantages for optoelectronic element and device driving, including enhanced switching speed through complementary transistor operation, greater rail-to-rail voltage swing capability, reduced static power dissipation, improved current control precision, wider dynamic range for brightness or sensitivity adjustment, symmetric sourcing and sinking capability, improved noise rejection through differential operation, and enhanced thermal management through distributed power dissipation across both transistor types.

In one example, a control signal generator provides complementary control signals to the gates of the PMOS and NMOS transistors such that when one transistor is driven into conduction, the other transistor is simultaneously driven to enhance or regulate the current path through the optoelectronic element. The complementary control signals may be derived from a single data signal through a signal conditioning circuit or may be independently generated to provide asymmetric control for applications requiring variable push-pull ratios.

In another example, the push-pull driving configuration is integrated into an active-matrix backplane where each pixel or sub-pixel comprises at least one PMOS transistor coupled to the anode and at least one NMOS transistor coupled to the cathode of the respective optoelectronic element. The active-matrix backplane may further include storage capacitors, scanning transistors, and data line drivers configured to support the complementary push-pull operation.

A method for driving an optoelectronic device includes providing a plurality of optoelectronic elements, each having independently addressable n-type cathode and p-type anode regions on an electrically inactive isolation region. The method further includes coupling a PMOS transistor to the anode region and an NMOS transistor to the cathode region of each element, and applying complementary control signals to drive both transistors in a push-pull configuration to regulate current through the optoelectronic element.

### Detailed Description

The following description sets forth examples of the push-pull complementary transistor driving configuration for optoelectronic devices in accordance with this technology. As used herein, the term “cathode” refers to an active n-type layer or region, the term “anode” refers to an active p-type layer or region, and the term “electrically inactive p-type isolation region” refers to a p-type region that is functionally electrically inactive in the operation of elements and provides electrical separation of individual cathodes from each other.

Referring to FIG. 1, the optoelectronic device structure leveraged by the present technology is illustrated. The device comprises a substrate 1, an optional buffer base region 3, an electrically inactive p-type isolation region 5 common to all optoelectronic elements, and for each element: a unique n-type cathode region 2, a MQW region 4 located over a portion of the cathode region 2, and a p-type anode region 6 located over the MQW region 4. The electrically inactive p-type isolation region 5 provides electrical isolation between the cathode regions 2 of adjacent elements through the formation of a depletion region at the p-n junction interface, thereby providing electrical isolation between adjacent elements.

A key enabler of the present technology is that each optoelectronic element in the device has both an independently addressable cathode region 2 and an independently addressable anode region 6. This dual independent addressability, provided by the electrically inactive p-type isolation region 5, allows both PMOS and NMOS transistors to be simultaneously coupled to a single optoelectronic element, with the PMOS transistor(s) coupled to anode region 6 and the NMOS transistor(s) coupled to the cathode region 2.

Referring to FIG. 2, a push-pull complementary transistor driving circuit for a single optoelectronic element 14 is schematically illustrated. The optoelectronic element 14 comprises an anode terminal connected to the p-type anode region 6 and a cathode terminal connected to the n-type cathode region 2. PMOS transistor(s) 12 are coupled between a supply voltage VDD and the anode terminal of the optoelectronic element 14. NMOS transistor(s) 13 are coupled between the cathode terminal of the optoelectronic element 14 and a ground reference (Gnd) or lower supply voltage. As illustrated, the PMOS transistor(s) 12 and NMOS transistor(s) 13 may each represent one or more transistors, depending on the particular circuit implementation. The use of block representations in FIG. 2 indicates that various transistor configurations and numbers may be employed within the push-pull topology without departing from the scope of this technology.

In operation of the push-pull circuit of FIG. 2, when the optoelectronic element 14 is to be driven into an active state, such as light emission in the case of an LED, the PMOS transistor(s) 12 are activated to source current from VDD through the anode terminal into the optoelectronic element 14. Simultaneously, the NMOS transistor(s) 13 are activated to sink the current exiting through the cathode terminal to ground. The optoelectronic element 14 is thus driven by a complementary push-pull action where the PMOS transistor(s) 12 push current into the element through the anode while the NMOS transistor(s) 13 pull current out through the cathode. The push-pull configuration provides several advantages over single-transistor-type driving approaches. In a conventional PMOS-only configuration, current is sourced through the anode while the cathode is connected to a common ground through a shared cathode structure, providing no active current regulation on the cathode side. Conversely, in an NMOS-only configuration, current is actively sunk through the cathode, but the anode side may rely on a passive connection to the supply. The push-pull configuration of the present technology actively controls both sides of the current path, providing enhanced performance.

Specifically, the push-pull complementary driving configuration provides enhanced switching speed. PMOS and NMOS transistors have complementary characteristics in that PMOS transistors are efficient at pulling output voltages toward VDD while NMOS transistors are efficient at pulling output voltages toward ground. In the push-pull configuration, each transistor type operates in its optimal region for its respective half of the switching transition. When transitioning the optoelectronic element 14 from an off state to an on state, the PMOS transistor(s) 12 efficiently charge the anode node while the NMOS transistor(s) 13 efficiently discharge the cathode node. This complementary action reduces the overall switching transition time compared to either transistor type alone, which is advantageous for the high refresh rates required by AR and VR displays or optical communication.

The push-pull configuration also provides reduced static power dissipation. In the push-pull topology, when the optoelectronic element 14 is in the off state, both transistor blocks can be fully turned off, resulting in negligible quiescent current. In contrast, certain single-transistor configurations may exhibit residual current paths. The complementary turn-off eliminates these parasitic current paths, reducing overall power consumption of the display or detector array.

Additionally, the push-pull configuration enables wider dynamic range for brightness or sensitivity control. By independently modulating the control signals to the PMOS transistor(s) 12 and the NMOS transistor(s) 13, the current through the optoelectronic element 14 can be controlled with greater precision across a wider range. The two transistor blocks can be operated in different regions, such as one in the linear region for fine control and the other in saturation for current limiting, enabling a broader and more linear range of drive currents. This is particularly advantageous for high dynamic range (HDR) displays requiring precise brightness control across multiple orders of magnitude.

Furthermore, the push-pull complementary configuration provides improved noise rejection. Noise on the supply voltage VDD is attenuated by the PMOS transistor(s) 12, while noise on the ground reference is attenuated by the NMOS transistor(s) 13. The differential nature of the push-pull topology provides common-mode rejection of noise that appears equally on both supply rails, resulting in cleaner drive current to the optoelectronic element 14 and more uniform emission or detection characteristics across the array.

Referring to FIG. 3, a push-pull driving circuit with control circuitry 20 is illustrated. The control circuitry 20 is coupled to the PMOS transistor(s) 12 and the NMOS transistor(s) 13 and provides the drive signals necessary to operate both transistor blocks in the push-pull configuration. The control circuitry 20 may encompass a broad range of circuit elements depending on the particular application and desired performance characteristics. By way of example and not limitation, the control circuitry 20 may include one or more scanning or row/column access transistors for addressing the pixel, one or more storage capacitors for holding data voltages during a frame period, signal conditioning or level shifting circuits for generating appropriate gate drive signals, threshold voltage compensation circuits, emission control switches, reset circuits, data line interface circuits, or any combination thereof.

In one example, the control circuitry 20 receives a data signal representative of a desired brightness or detection sensitivity level and generates appropriate drive signals for the PMOS transistor(s) 12 and NMOS transistor(s) 13. The control circuitry 20 may generate complementary signals such that when the PMOS transistor(s) 12 are driven into conduction, the NMOS transistor(s) 13 are simultaneously driven to sink the resulting current through the optoelectronic element 14. In another example, the control circuitry 20 may generate independently controlled signals for the PMOS transistor(s) 12 and NMOS transistor(s) 13, allowing asymmetric push-pull ratios where, for example, one transistor block provides a larger fraction of the current regulation than the other.

The control circuitry 20 may further be configured to implement timing control for the push-pull operation, as described more fully with reference to FIG. 5. By way of example, the control circuitry 20 may generate drive signals with a controlled non-overlap period during which both the PMOS transistor(s) 12 and the NMOS transistor(s) 13 are momentarily in an off state, preventing shoot-through current from VDD to ground during transitions. Alternatively, the control circuitry 20 may implement a controlled overlap period to ensure continuous current flow through the optoelectronic element 14 during transitions, avoiding visible flicker. The choice of overlap or non-overlap timing, as well as the duration of such periods, can be tailored to the requirements of the particular application.

The specific implementation of the control circuitry 20 can range from a simple configuration, such as an active-matrix circuit with a small number of transistors and a single storage capacitor, to more complex configurations incorporating many transistors and multiple capacitors for functions such as threshold voltage compensation, aging compensation, current programming, or other performance-enhancing features. The push-pull driving topology of the present technology is compatible with and benefits from any such configuration, as the fundamental push-pull operation of the PMOS transistor(s) 12 and NMOS transistor(s) 13 remains consistent regardless of the complexity of the associated control circuitry 20.

Referring to FIG. 4, a cross-sectional view of an optoelectronic system 400 incorporating the push-pull complementary driving configuration is illustrated. The system 400 comprises an optoelectronic array layer 410 bonded to a CMOS backplane layer 420. The optoelectronic array layer 410 comprises the structure described with reference to FIG. 1, including the substrate 1, optional buffer base region 3, electrically inactive p-type isolation region 5, and a plurality of optoelectronic elements each having unique cathode regions 2, MQW regions 4, and anode regions 6. Metal contacts including n-type contacts 7 on the cathode regions 2 and p-type contacts 8 on the anode regions 6 are formed, along with a dielectric spacer 9 for electrical isolation and protection. An optional black matrix 19 may be formed on the substrate 1 or bugger layer 3 to provide additional light blocking.

The CMOS backplane layer 420 is fabricated using standard CMOS processing and includes both PMOS transistor(s) 12 and NMOS transistor(s) 13 for each pixel or sub-pixel location. The CMOS backplane layer 420 is bonded to the optoelectronic array layer 410 through bonding interconnects 450 which provide electrical connections between the p-type contacts 8 and the PMOS transistor(s) 12, and between the n-type contacts 7 and the NMOS transistor(s) 13. The bonding interconnects 450 may comprise, by way of example, hybrid bonding pads, micro-bumps, or other interconnect structures suitable for high-density array bonding. A significant advantage of the bonded CMOS backplane configuration is that both PMOS and NMOS transistors are fabricated on the same silicon wafer using standard CMOS foundry processes. Standard CMOS processes are inherently complementary, providing both PMOS and NMOS transistors as a fundamental capability. The push-pull driving configuration of the present technology thus leverages the full capability of standard CMOS processing without requiring any specialized or non-standard fabrication steps for the backplane. This provides significant cost and manufacturing yield advantages over approaches requiring specialized processing.

Alternatively, the push-pull complementary driving configuration is compatible with monolithic optoelectronic device architectures where the driving circuitry and optoelectronic elements share a common material system. In the monolithic case, NMOS and PMOS transistors may be formed in the same material system as the optoelectronic elements, such as GaN-based CMOS transistors.

Referring to FIG. 5, a timing diagram illustrating exemplary complementary control signals applied to the PMOS transistor(s) 12 and NMOS transistor(s) 13 during operation of the push-pull driving configuration is shown. The timing diagram depicts four signals over three operating periods: a scan period, an emission period, and a blanking period.

During the scan period, a scan signal VSCAN is asserted as a pulse to activate a scanning or access transistor within the control circuitry 20, writing a data voltage to a storage element such as a storage capacitor. During the scan period, both the PMOS gate drive signal VP and the NMOS gate drive signal VN are held in states that maintain the PMOS transistor(s) 12 and NMOS transistor(s) 13 in the off condition, such that no current flows through the optoelectronic element 14 during data loading.

Following the scan period, the emission period begins. The PMOS gate drive signal VP transitions to a low state to activate the PMOS transistor(s) 12, sourcing current from VDD into the anode of the optoelectronic element 14. The NMOS gate drive signal VN transitions to a high state to activate the NMOS transistor(s) 13, sinking current from the cathode of the optoelectronic element 14 to ground. As shown in FIG. 5, a controlled dead time tdead is provided between the transition of VP and the transition of VN. During this dead time, both the PMOS transistor(s) 12 and the NMOS transistor(s) 13 are in the off state, preventing a direct current path from VDD to ground through the transistors, commonly referred to as shoot-through current. The current through the optoelectronic element 14, represented as ILED, ramps up as both transistors become fully active, reaching a steady-state value determined by the data voltage and transistor operating points.

At the end of the emission period, the transition to the blanking period similarly includes a dead time tdead. The NMOS gate drive signal VN transitions to a low state first, beginning to turn off the NMOS transistor(s) 13. After the dead time, the PMOS gate drive signal VP transitions to a high state, turning off the PMOS transistor(s) 12. The current ILED through the optoelectronic element 14 ramps down to zero as the transistors are deactivated. During the blanking period, both VP and VN are held in states that maintain both transistor blocks in the off condition, and no current flows through the optoelectronic element 14.

The dead time tdead may be adjusted based on the specific transistor characteristics and application requirements. A shorter dead time minimizes the period of reduced current during transitions, while a longer dead time provides greater margin against shoot-through current. In an alternative embodiment, the dead time may be eliminated entirely, with VP and VN transitioning simultaneously or with controlled overlap to maintain continuous current flow through the optoelectronic element 14 during transitions. The timing relationships illustrated in FIG. 5 are exemplary and may be modified as appropriate for different implementations of the push-pull driving configuration.

In further examples of this technology, the push-pull complementary driving configuration can be applied to optoelectronic elements functioning as detectors. In a detector application, the PMOS and NMOS transistors provide complementary active readout of the photocurrent generated in the optoelectronic element 14. The push-pull readout configuration provides enhanced sensitivity, wider dynamic range, and improved noise rejection compared to single-transistor readout configurations.

In further examples, the push-pull complementary driving configuration is applied to optoelectronic elements within optical transceiver arrays used in data center switch-to-server and rack-to-rack interconnects. In such applications, each optoelectronic element in the array functions as a high-speed optical transmitter or receiver operating at data rates of 100 Gbps per lane or higher. The dual-rail push-pull drive provided by the complementary PMOS and NMOS transistors enables faster modulation of the optoelectronic element, increasing the achievable modulation bandwidth and supporting higher aggregate data throughput per fiber or waveguide channel. The enhanced switching speed of the push-pull configuration is particularly advantageous for next-generation 800G and 1.6T optical link standards, where each lane must operate at 100G or 200G signaling rates with stringent eye-diagram margins.

In another example, the push-pull complementary driving configuration is particularly suited for optoelectronic elements deployed within co-packaged optics (CPO) architectures, where optoelectronic arrays are integrated directly onto or immediately adjacent to switch ASICs within data center network equipment. In CPO configurations, the optoelectronic elements and their driving circuitry operate within a thermally constrained package where power dissipation directly impacts the thermal budget available to the switch ASIC. The reduced static power dissipation of the push-pull configuration, achieved through complementary turn-off of both PMOS and NMOS transistors during inactive periods, is critical in such thermally limited environments. Furthermore, the improved noise rejection provided by the differential push-pull topology enhances signal integrity in the electrically noisy environment of a co-packaged module, where high-speed digital switching activity of the adjacent ASIC can couple into the analog drive circuits of the optoelectronic elements.

Referring to FIG. 6, a data center optical interconnect system is illustrated showing two exemplary deployment configurations of the push-pull complementary driving configuration. A network switch rack includes a switch ASIC with SerDes lanes coupled to a co-packaged optics module containing a μLED TX array and a detector RX array, each driven by CMOS backplane dual-rail drivers employing the push-pull configuration. A compute server rack includes a GPU or AI accelerator coupled through a network interface to a pluggable optical transceiver (OSFP) similarly containing a μLED TX array, a detector RX array, and CMOS backplane dual-rail drivers. The two racks are connected by an optical fiber bundle supporting 800G or 1.6T aggregate data rates over distances of up to 100 meters. A detail view illustrates a single optoelectronic element 14 driven by PMOS transistor(s) 12 and NMOS transistor(s) 13 in the push-pull configuration on CMOS backplane layer 420, connected through bonding interconnects 450, as described with reference to FIGS. 2 and 4.

In another example, the push-pull configuration enables a current steering mode where the relative drive strengths of the PMOS transistor(s) 12 and NMOS transistor(s) 13 are modulated to steer current through the optoelectronic element 14 with high precision. By operating one transistor block in the linear region as a variable resistance and the other in saturation as a current source, or vice versa, the effective drive current can be controlled with high linearity over a wide range. This current steering capability is particularly advantageous for display applications requiring gamma correction or for detector applications requiring adjustable sensitivity.

Accordingly, as illustrated and described by way of the examples herein, the push-pull complementary transistor driving configuration of this technology provides enhanced device switching speeds, improved power efficiency, wider dynamic range, better noise rejection, and greater design flexibility compared to single-transistor-type driving approaches. Modeling representative push-pull configurations indicates that switching rise and fall times can be reduced by greater than 50% relative to conventional single-transistor pull-up or pull-down driver topologies, owing to the active driving of both the anode and cathode terminals of the light-emitting element and the elimination of residual conducted current during the off-state. This improvement in switching speed directly translates to increased achievable data rates per optical channel. Furthermore, the push-pull configuration can reduce average power dissipation by greater than 40% compared to single-transistor configurations operating at the same modulation frequency, primarily through the suppression of off-state leakage current that arises in single-ended topologies where one terminal of the light-emitting element remains connected to a supply rail. The optical extinction ratio, a critical figure of merit for optical communication link performance, can be improved by greater than 15 dB through the push-pull approach, as the high-impedance off-state on both terminals of the light-emitting element substantially eliminates residual photon emission during logical zero transmission. These performance advantages are geometry-independent and scale across a range of device sizes, drive current levels, and modulation frequencies, as they arise from the circuit topology rather than from specific device dimensions. These advantages are particularly beneficial for high-resolution micro-LED displays, high-performance detector arrays, data center optical interconnects, co-packaged optics, and optical transceiver arrays operating under demanding performance requirements, such as those for AR and VR applications, AI data center infrastructure, and next-generation 800G and 1.6T optical communication links. The push-pull configuration fully leverages the independently addressable cathode and anode architecture enabled by the electrically inactive p-type isolation region.

Having thus described the basic concept of the technology, the foregoing detailed disclosure is intended to be presented by way of example only and is not limiting. Various other examples, alterations, improvements, and modifications will occur and are intended to those skilled in the art, though not expressly stated herein. These alterations, improvements, and modifications are intended to be suggested hereby, and are within the spirit and scope of the technology. Additionally, the recited order of processing elements or sequences, or the use of numbers, letters, or other designations therefore, is not intended to limit the scope of the present invention.

What is claimed is:

1. An optoelectronic device having current flow, data throughput and power consumption, said optoelectronic device comprising:
a plurality of optoelectronic elements, each of said plurality of optoelectronic elements are physically and electrically isolated in said device on an electrically inactive isolation region common to all of said plurality of optoelectronic elements, wherein each of said plurality of optoelectronic elements includes:
an n-type cathode region;
an MQW region located over a portion of said n-type cathode region;
a p-type anode region located over said MQW region;
at least one PMOS transistor coupled to said p-type anode region; and
at least one NMOS transistor coupled to said n-type cathode region,
wherein said at least one PMOS transistor and said at least one NMOS transistor are simultaneously and independently controllable in a push-pull complementary driving configuration to provide a source current through said p-type anode region and a sink current through said n-type cathode region, respectively, to vary current flow, said data throughput, and said power consumption in said optoelectronic device.

2. The optoelectronic device as set forth in claim 1, further including an electrically inactive isolation region having an electrically inactive p-type isolation region that forms a depletion region with said n-type cathode region to electrically isolate each of said plurality of optoelectronic elements from each other.

3. The optoelectronic device as set forth in claim 1, further comprising control circuitry coupled to said at least one PMOS transistor and said at least one NMOS transistor, wherein said control circuitry is configured to generate drive signals for operating said at least one PMOS transistor and said at least one NMOS transistor in said push-pull complementary driving configuration.

4. The optoelectronic device as set forth in claim 3, wherein said control circuitry comprises a scanning transistor, a storage capacitor, a signal conditioning circuit, a threshold voltage compensation circuit, and an emission control switch.

5. The optoelectronic device as set forth in claim 3, wherein said control circuitry is configured to generate drive signals with a non-overlap period during which said at least one PMOS transistor and said at least one NMOS transistor are simultaneously in an off state.

6. The optoelectronic device as set forth in claim 1, wherein said at least one coupled PMOS transistor and said at least one NMOS transistor are elements of a CMOS backplane wafer.

7. The optoelectronic device as set forth in claim 6, wherein said CMOS backplane wafer is bonded to an optoelectronic array through bonding interconnects that provide electrical connections between said p-type anode region and said at least one PMOS transistor, and between said n-type cathode region and said at least one NMOS transistors.

8. The optoelectronic device as set forth in claim 1, wherein said plurality of optoelectronic elements each comprise a micro-LED having a lateral dimension of less than 100 micrometers.

9. The optoelectronic device as set forth in claim 1, wherein said at least one PMOS transistor and said at least one NMOS transistor are independently controllable to provide asymmetric push-pull driving with a variable ratio of current sourced through said p-type anode region to current sunk through said n-type cathode region.

10. The optoelectronic device as set forth in claim 1, wherein said plurality of optoelectronic elements each comprise a light absorbing detector, and said at least one PMOS transistor and said at least one NMOS transistor are configured in a push-pull complementary readout configuration.

11. A method for driving an optoelectronic device having a plurality of optoelectronic elements, wherein each of said plurality of optoelectronic elements is physically and electrically spaced from each other on an electrically inactive isolation region common to all of the elements, and wherein each of said plurality of optoelectronic elements have an n-type cathode region, an MQW region, and a p-type anode region, the method comprising:
coupling sat at least one PMOS transistor to said p-type anode region of each of said plurality of optoelectronic elements;
coupling said at least one NMOS transistor to said n-type cathode region of each of said at least one optoelectronic elements; and
applying control signals to said PMOS transistor and said at least one NMOS transistor to drive said at least one PMOS transistor and said at least one NMOS transistor in a push-pull configuration, wherein said at least one PMOS transistor provides a source current into one of said plurality of optoelectronic elements through said p-type anode region and said at least one NMOS transistor provides a sink current from said one of said plurality of optoelectronic elements through said n-type cathode region.

12. The method as set forth in claim 11, further comprising generating said control signals using control circuitry that includes a scanning transistor, a storage capacitor, a signal conditioning circuit, and a combination thereof.

13. The method as set forth in claim 11, further comprising controlling a non-overlap timing between said control signals to prevent simultaneous conduction of said at least one PMOS transistor and said at least one NMOS transistor during a switching transition.

14. The method as set forth in claim 11, further comprising independently modulating drive signals of said at least one PMOS transistor and said at least one NMOS transistor to control a dynamic range of current through said plurality of optoelectronic elements.

15. The method as set forth in claim 11, further comprising:
during an emission period, activating both said at least one PMOS transistor and said at least one NMOS transistor to drive current through said plurality of optoelectronic elements; and
during a blanking period, deactivating both said at least one PMOS transistor and said at least one NMOS transistor to terminate a current flow through said plurality of optoelectronic elements.

16. The method as set forth in claim 11, wherein coupling comprises bonding a CMOS backplane wafer containing said at least one PMOS transistor and said at least one NMOS transistor to an optoelectronic array containing said plurality of optoelectronic elements.

17. The method as set forth in claim 11, further comprising operating said at least one PMOS transistor or said at least one NMOS transistor in a linear region and in a saturation region to provide current steering with high linearity.

18. An optoelectronic system comprising:
an optoelectronic array layer comprising:
a plurality of optoelectronic elements on an electrically inactive p-type isolation region, each of said plurality of optoelectronic elements including;
an independently addressable n-type cathode region and an independently addressable p-type anode region separated by an MQW region; and
a CMOS backplane layer bonded to said optoelectronic array layer, wherein said CMOS backplane layer contains for each of said plurality of optoelectronic elements:
at least one PMOS transistor electrically connected to said independently addressable p-type anode region, and
at least one NMOS transistor electrically connected to said independently addressable n-type cathode region,
wherein said at least one PMOS transistor and said at least one NMOS transistor are configured to operate in a complementary push-pull mode to regulate current through said plurality of optoelectronic elements.

19. The optoelectronic system as set forth in claim 18, further comprising control circuitry for each of said plurality of optoelectronic elements, wherein said control circuitry is configured to generate drive signals for said at least one PMOS transistor and said at least one NMOS transistor.

20. The optoelectronic system as set forth in claim 18, wherein said CMOS backplane layer is fabricated using a CMOS foundry process and is bonded to said optoelectronic array layer through bonding interconnects.
